(19) United States
(12) Patent Application Publication
(10) Pub. No.: US 2025/0165169 A1
(43) Pub. Date: May 22, 2025

(54) MEMORY SYSTEMS, OPERATING METHODS THEREOF, AND STORAGE MEDIA

(71) Applicant: YANGTZE MEMORY TECHNOLOGIES CO., LTD., Wuhan (CN)

(72) Inventor: Baijun HU, Wuhan (CN)

(21) Appl. No.: 18/639,709

(22) Filed: Apr. 18, 2024

(30) Foreign Application Priority Data
Nov. 20, 2023 (CN) 2023115618025

(51) Int. Cl. G06F 3/06

(52) U.S. Cl. CPC G06F 3/0634; G06F 3/0604; G06F 3/064; G06F 3/0679

(57) ABSTRACT

Implementations of the present disclosure provide a memory system, an operating method thereof, and a storage medium. The memory system comprises: a memory device including a plurality of blocks, wherein a block includes a plurality of memory cells; a memory controller coupled to the memory device and configured to: determine a storage mode for a block based on a total amount of valid data in all of the plurality of blocks; wherein data reading and writing with different rates are to be performed for different storage modes by configuring the number of data bits stored in each memory cell in the block.

### CROSS-REFERENCE TO RELATED APPLICATIONS

The present application claims priority to Chinese Patent Application No. 2023115618025, which was filed Nov. 20, 2023, is titled “MEMORY SYSTEM AND ITS OPERATING METHOD, STORAGE MEDIUM,” and is hereby incorporated herein by reference in its entirety.

### TECHNICAL FIELD

Implementations of the present disclosure relate to the technical field of semiconductors, and more particularly to a memory system, an operating method thereof, and a storage medium.

### BACKGROUND

Memory devices are storage devices for storing information in modern information technology. As typical non-volatile semiconductor memory, NAND (Not-And) memory has gradually become the mainstream product in the memory market because of its high storage density, controllable production cost, suitable programming and erasing speed and retention characteristics.

### SUMMARY

In view of the above, implementations of the present disclosure provide a memory system, an operating method thereof, and a storage medium.

An implementation of the present disclosure provides a memory system, comprising: a memory device including a plurality of blocks, wherein a block includes a plurality of memory cells; a memory controller coupled to the memory device and configured to: determine a storage mode for a block based on a total amount of valid data in all of the plurality of blocks; wherein data reading and writing with different rates are to be performed for different storage modes by configuring the number of data bits stored in each memory cell in the block.

In some implementations, the memory controller is configured to: acquire the total amount of valid data in all of the plurality of blocks; calculate a ratio of the total amount of valid data to a total memory space of the plurality of blocks to obtain a proportion of valid data; determine, based on the proportion of valid data, the storage mode for a new block to be opened.

In some implementations, the storage modes comprise a first mode and a second mode; wherein in the first mode, the data bits stored in each memory cell of the block comprise one bit; and in the second mode, the data bits stored in each memory cell of the block comprise multiple bits; the memory controller is configured to: configure dynamically the number of blocks adopting the first mode when the proportion of valid data is greater than or equal to a first threshold; stop configuring dynamically the number of blocks adopting the first mode when the proportion of valid data is greater than or equal to a second threshold; wherein the first threshold is less than the second threshold.

In some implementations, the memory controller is configured to: configure the number of blocks adopting the first mode to be a first number when the proportion of valid data is a first proportion; configure the number of blocks adopting the first mode to be a second number when the proportion of valid data is a second proportion; configure the number of blocks adopting the first mode to be a third number when the proportion of valid data is a third proportion; wherein the first proportion is less than the second proportion, and the second proportion is less than the third proportion; the first number is greater than the second number, and the second number is greater than the third number.

In some implementations, the proportion of valid data is linearly correlated with the number of blocks adopting the first mode, both between the first proportion and the second proportion and between the second proportion and the third proportion; a ratio of a difference between the second number and the first number to a difference between the second proportion and the first proportion is different from a ratio of a difference between the third number and the second number to a difference between the third proportion and the second proportion.

In some implementations, the memory controller is configured to: query a target mapping table using the proportion of valid data to determine the number of blocks adopting the first mode; the target mapping table includes a correspondence relationship between values of different proportions of valid data and corresponding numbers of blocks adopting the first mode.

In some implementations, the memory controller is further configured to: select the target mapping table from among a plurality of mapping tables before querying the target mapping table; the correspondence relationship between the different proportions of valid data and the corresponding numbers of blocks adopting the first mode, contained in each of the plurality of mapping tables, is different from one another.

In some implementations, the memory controller is further configured to: in response to a new block needs to be opened for data writing: configure the new block to perform the data writing with the first mode when the number of blocks adopting the first mode determined based on the proportion of valid data is greater than the current number of blocks actually adopting the first mode; configure the new block to perform the data writing with the second mode when the number of blocks adopting the first mode determined based on the proportion of valid data is less than or equal to the current number of blocks actually adopting the first mode.

In some implementations, a block comprises a plurality of pages; the memory controller is further configured to: acquire a count of pages occupied by valid data in all of the plurality of blocks to obtain the total amount of valid data.

In some implementations, the valid data includes data that has not been erased, indicated to be erased, updated or rewritten by a host system.

Further, an implementation of the present disclosure provides an operating method of a memory system, comprising: determining a storage mode for a block based on a total amount of valid data in all of a plurality of blocks in a memory device of the memory system; wherein data reading and writing with different rates are to be performed for different storage modes by configuring the number of data bits stored in each memory cell in the block.

In some implementations, the method further comprises: acquiring the total amount of valid data in all of the plurality of blocks; calculating a ratio of the total amount of valid data to a total memory space of the plurality of blocks to obtain the proportion of valid data; determining, based on the proportion of valid data, the storage mode for a new block to be opened.

In some implementations, the storage modes comprise a first mode and a second mode; wherein in the first mode, the data bits stored in each memory cell of the block comprise one bit; and in the second mode, the data bits stored in each memory cell of the block comprise multiple bits; determining, based on the proportion of valid data, the storage mode for the block comprises: configuring dynamically the number of blocks adopting the first mode when the proportion of valid data is greater than or equal to a first threshold; stopping configuring dynamically the number of blocks adopting the first mode when the proportion of valid data is greater than or equal to a second threshold; wherein the first threshold is less than the second threshold.

In some implementations, the method further comprises: configuring the number of blocks adopting the first mode to be a first number when the proportion of valid data is a first proportion; configuring the number of blocks adopting the first mode to be a second number when the proportion of valid data is a second proportion; configuring the number of blocks adopting the first mode to be a third number when the proportion of valid data is a third proportion; wherein the first proportion is less than the second proportion, and the second proportion is less than the third proportion; the first number is greater than the second number, and the second number is greater than the third number.

In some implementations, the proportion of valid data is linearly correlated with the number of blocks adopting the first mode, both between the first proportion and the second proportion and between the second proportion and the third proportion; a ratio of a difference between the second number and the first number to a difference between the second proportion and the first proportion is different from a ratio of a difference between the third number and the second number to a difference between the third proportion and the second proportion.

In some implementations, the method further comprises: querying a target mapping table using the proportion of valid data to determine the number of blocks adopting the first mode; the target mapping table includes a correspondence relationship between values of different proportions of valid data and corresponding numbers of blocks adopting the first mode.

In some implementations, the method further comprises: selecting the target mapping table from among a plurality of mapping tables before querying the target mapping table; the correspondence relationship between the different proportions of valid data and the corresponding numbers of blocks adopting the first mode, contained in each of the plurality of mapping tables, is different from one another.

In some implementations, the method further comprises: in response to a new block needs to be opened for data writing: configuring the new block to perform the data writing with the first mode when the number of blocks adopting the first mode determined based on the proportion of valid data is greater than the current number of blocks actually adopting the first mode; configuring the new block to perform the data writing with the second mode when the number of blocks adopting the first mode determined based on the proportion of valid data is less than or equal to the current number of blocks actually adopting the first mode.

In some implementations, a block comprises a plurality of pages; acquiring the total amount of valid data in all of the plurality of blocks comprises: acquiring a count of pages occupied by valid data in all of the plurality of blocks to obtain the total amount of valid data.

In some implementations, the valid data includes data that has not been erased, indicated to be erased, updated or rewritten by a host system.

Still further, an implementation of the present disclosure provides a storage medium having stored thereon executable instructions which, when being executed, may implement operations of the method of the implementations of the present disclosure.

In the implementations of the present disclosure, the memory controller in the memory system determines a storage mode for a block based on a total amount of valid data in all of the plurality of blocks of the memory device; wherein data reading and writing with different rates are to be preformed for different storage modes by configuring the number of data bits stored in each memory cell in the block. In the implementations of the present disclosure, the storage mode for a block is determined based on the total amount of valid data in all of the plurality of blocks in the memory device, thus the misjudgment that may occur when the distribution of valid data in most or all of blocks is low can be avoided, thereby being applicable to a wide range of application scenarios.

### BRIEF DESCRIPTION OF THE DRAWINGS

FIG. 1 is a schematic diagram of an exemplary system having a memory system according to an implementation of the present disclosure;

FIG. 2A is a schematic diagram of an exemplary memory card having a memory system according to an implementation of the present disclosure;

FIG. 2B is a schematic diagram of an exemplary solid-state drive having a memory system according to an implementation of the present disclosure;

FIG. 3A is a schematic diagram showing the distribution of memory cells of a three-dimensional NAND-type memory according to an implementation of the present disclosure;

FIG. 3B is a schematic diagram of an exemplary memory including peripheral circuits according to an implementation of the present disclosure;

FIG. 4 is a schematic cross-sectional view of a memory cell array including a NAND-type memory string according to an implementation of the present disclosure;

FIG. 5 is a schematic diagram of an exemplary memory device including a memory cell array and a peripheral circuit according to an implementation of the present disclosure;

FIG. 6 is a schematic diagram showing an exemplary composition structure of a memory system according to an implementation of the present disclosure;

FIG. 7A is a schematic diagram of an exemplary relationship between the number of blocks adopting a first mode and the proportion of valid data provided by an implementation of the present disclosure;

FIG. 7B is a schematic diagram of an exemplary relationship between the number of blocks adopting a first mode and the proportion of valid data provided by an implementation of the present disclosure;

FIG. 7C is a schematic diagram of an exemplary relationship between the number of blocks adopting a first mode and the proportion of valid data provided by an implementation of the present disclosure; and

FIG. 8 is a schematic block diagram of a readable storage medium provided by an implementation of the present disclosure.

Similar reference numerals in the above drawings (which are not necessarily drawn to scale) may describe similar components in different views. Similar reference numerals with different letter suffixes may denote different examples of similar components. The drawings generally illustrate, by way of example and not limitation, various implementations discussed herein.

### DETAILED DESCRIPTION

The exemplary implementations of the present disclosure will be described in more detail below with reference to the accompanying drawings. Although exemplary implementations of the present disclosure are shown in the accompanying drawings, the present disclosure may be embodied in various forms and should not be limited by the exemplary implementations set forth herein. Rather, these implementations are provided to enable a more thorough understanding of the present disclosure and to fully convey the scope of the present disclosure to those skilled in the art.

Specific details are given in the following description to provide a more thorough understanding of the present disclosure. However, it will be apparent to those skilled in the art that the present disclosure may be practiced without one or more of these details. Some technical features well known in the art are not described in other examples to avoid confusion with the present disclosure. That is, not all the features of the actual implementations are described herein, and the well-known functions and structures are not described in detail.

In the accompanying drawings, the sizes of layers, zones and elements as well as and the relative sizes thereof may be exaggerated for the sake of clarity. The same reference numerals denote the same elements throughout.

When an element or a layer is referred to as being “on”, “adjacent to”, “connected to” or “coupled to” other elements or layers, it may be directly on, adjacent to, connected to or coupled to other elements or layers, or there may be intervening elements or layers. Conversely, when an element is referred to as being “directly on”, “directly adjacent to”, “directly connected to”, or “directly coupled to” other elements or layers, there are no intervening elements or layers. Although the terms “first”, “second”, “third”, and the like may be used to describe various elements, parts, zones, layers, and/or portions, these elements, parts, zones, layers, and/or portions should not be limited by these terms. These terms are used only to distinguish one element, part, zone, layer, or portion from another element, part, zone, layer, or portion. Thus, without departing from the teachings of the present disclosure, the first element, part, zone, layer, or portion discussed below may be represented as a second element, part, zone, layer, or portion. When a second element, part, zone, layer, or portion is discussed, it does not mean that a first element, part, zone, layer, or portion necessarily exists in the present disclosure.

The spatial relationship terms such as “under”, “below”, “lower”, “beneath”, “above”, “upper”, and the like may be used herein for ease of description, thereby describing the relationship of one element or feature shown in the drawings with other elements or features. In addition to the orientations shown in the drawings, the spatial relationship terms may be intended to include different orientations of a device in use and operation. For example, if the device in the accompanying drawings is turned over, then the element or feature described as “below” or “beneath” or “under” other elements can be oriented to be “on” the other elements or features. Thus, the exemplary terms “below” and “under” may include both up and down orientations. The device may be oriented in other ways (rotated 90 degrees or in other orientations) and the spatial description terms used herein are to be interpreted accordingly.

The terms used herein are for the purpose of describing exemplary implementations only and are not regarded as limitations of the present disclosure. When used herein, the singular forms “a”, “an”, and “the/said” are also intended to include the plural forms, unless otherwise indicated clearly under the context. The terms “comprising” and/or “including”, when used in this specification, can identify the presence of the features, integers, steps, operations, elements and/or parts, but do not exclude the presence or addition of one or more other features, integers, steps, operations, elements, parts and/or groups. When used herein, the term “and/or” may include each and every combination of the relevant listed items.

In order to provide a more detailed understanding of the features and technical aspects of implementations of the present disclosure, the implementations of the present disclosure are described in detail below by referring to the accompanying drawings, which are provided for illustrative purposes only and are not intended to limit the implementations of the present disclosure.

The memory device in the implementations of the present disclosure includes, but are not limited to, three-dimensional NAND-type memory, which is taken as an example for case of understanding.

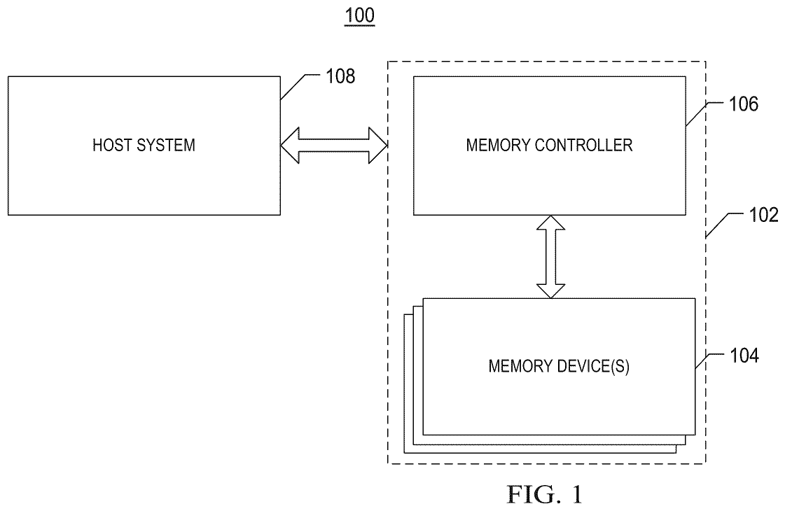

FIG. 1 illustrates a block diagram of an exemplary system 100 having memory device(s) according to some aspects of the present disclosure. The system 100 may be a mobile phone, a desktop computer, a laptop computer, a tablet computer, an in-vehicle computer, a game console, a printer, a positioning device, a wearable electronic device, a smart sensor, a virtual reality (VR) device, an augmented reality (AR) device or any other suitable electronic device having memory therein. As shown in FIG. 1, the system 100 may include a host system 108 and a memory system 102 having one or more memory devices 104 and a memory controller 106. The host system 108 may comprise a processor (e.g., a central processing unit (CPU)) or a system-on-chip (SoC) (e.g., an application processor (AP)) of an electronic device. The host system 108 may be configured to send data to or receive data from the memory device 104.

The memory controller 106 is coupled to the memory device 104 and the host system 108 and is configured to control the memory device 104, according to some implementations. The memory controller 106 may manage data stored in the memory device 104 and communicate with the host system 108. In some implementations, the memory controller 106 is designed to operate in a low-duty-cycle environment, such as a secure digital (SD) card, a compact flash (CF) card, a universal serial bus (USB) flash drive, or other media for use in electronic devices such as personal calculators, digital cameras, mobile phones, and the like. In some implementations, the memory controller 106 is designed to operate in a high-duty-cycle environment, such as a solid state disk (SSD) or an embedded multimedia card (eMMC), wherein the SSD or eMMC is used as data memory for mobile devices such as smart phones, tablet computers, laptops and the like, and as enterprise memory array.

The memory controller 106 may be configured to control operations of the memory device 104, such as read, erase and program operations. The memory controller 106 may also be configured to manage various functions relating to data stored or to be stored in the memory device 104, including but not limited to bad block management, garbage collection, logic to physical address translation, wear leveling, and the like. In some implementations, the memory controller 106 is further configured to process error correction codes (ECC) on data read from or written to the memory device 104. The memory controller 106 may also perform any other suitable function such as formatting the memory device 104. The memory controller 106 may communicate with external devices (e.g., host system 108) according to particular communication protocols. For example, the memory controller 106 may communicate with the external devices through at least one of various interface protocols, such as USB protocol, MMC protocol, peripheral component interconnect (PCI) protocol, PCI-express (PCI-E) protocol, advanced technology attachment (ATA) protocol, serial ATA protocol, parallel ATA protocol, small computer small interface (SCSI) protocol, enhanced small disk interface (ESDI) protocol, integrated drive electronics (IDE) protocol, firmware protocol, and the like.

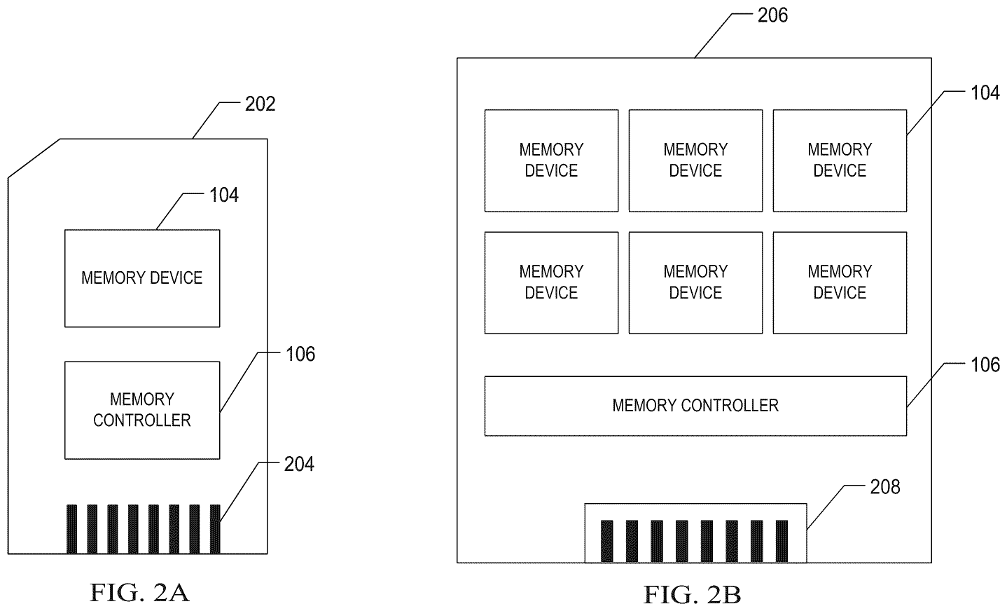

The memory controller 106 and one or more memory devices 104 may be integrated into various types of storage devices, e.g., included in the same package (e.g., Universal Flash Storage (UFS) package or eMMC package). That is, the memory system 102 may be implemented and packed into different types of terminal electronics. In an example as shown in FIG. 2A, the memory controller 106 and a single memory device 104 may be integrated into a memory card 202. The memory card 202 may include a PC card (PCMCIA, Personal Computer Memory Card International Association), a CF card, a smart media (SM) card, a memory stick, a multimedia card (MMC, RS-MMC, MMCmicro), a SD card (SD, miniSD, microSD, SDHC), a UFS, or the like. The memory card 202 may also include a memory card connector 204 that couples the memory card 202 to a host (e.g., host system 108 in FIG. 1). In another example as shown in FIG. 2B, the memory controller 106 and a plurality of memory devices 104 may be integrated into the SSD 206. The SSD 206 may also include an SSD connector 208 that couples the SSD 206 to a host (e.g., host system 108 in FIG. 1). In some implementations, the storage capacity and/or operating speed of the SSD 206 is greater than those of the memory card 202.

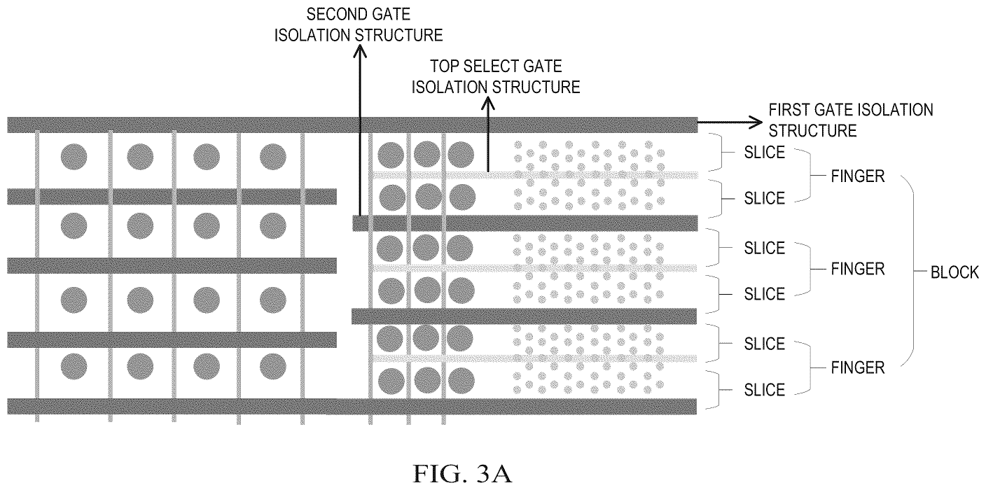

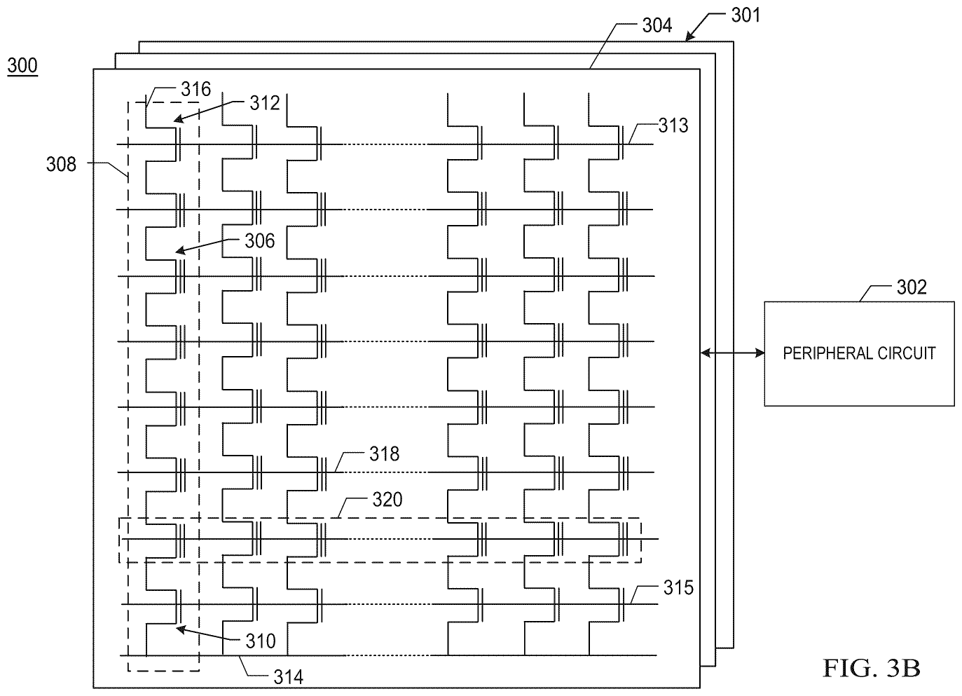

FIG. 3A exemplarily shows a schematic diagram of the structure of a memory cell array of a 3D NAND-type memory. As shown in FIG. 3A, the memory cell array of the 3D NAND-type memory is composed of a plurality of parallel staggered memory cell rows that are parallel to a gate isolation structure. Every certain number of memory cell rows are separated by the gate isolation structure and a top select gate isolation structure. Each of the memory cell rows includes a plurality of memory cells. The gate isolation structure may include a first gate isolation structure that divides the memory cell array into a plurality of blocks and a second gate isolation structure that divides a block into a plurality of fingers. The top select gate isolation structure provided in each finger may divide the finger into two parts, so as to divide the finger into two slices. One block shown in FIG. 3A includes six slices, however the number of slices in one block is not limited thereto in practice.

In some implementations, each block may be coupled with a plurality of word lines.

The number of memory cell rows between the gate isolation structure and the top select gate isolation structure shown in FIG. 3A is exemplary only and is not intended to limit the number of memory cell rows included in one finger of the 3D NAND-type memory in the present disclosure. In practice, the number of memory cell rows contained in a finger may be adjusted according to the actual situation, such as 2, 4, 8, 16, or the like.

FIG. 3B shows a schematic circuit diagram of an exemplary memory device 300 including a peripheral circuit according to some aspects of the present disclosure. The memory device 300 may be an example of the memory device 104 in FIG. 1. The memory device 300 may include a memory cell array 301 and a peripheral circuit 302 coupled to the memory cell array 301. The memory cell array 301 may be illustrated as example of a 3D NAND-type memory cell array, in which memory cells 306 are NAND-type memory cells and provided in the form of an array of memory strings 308, which each extend vertically above a substrate (not shown). In some implementations, each memory string 308 includes multiple memory cells 306 coupled in series and stacked vertically. Each memory cell 306 can hold a continuous analog value, e.g., voltage or charge, that depends on the number of electrons trapped within an area of the memory cell 306. Each memory cell 306 may be a floating gate-type memory cell including a floating gate transistor, or a charge trapping-type memory cell including a charge trapping transistor.

In some implementations, each memory cell 306 may be a single level cell (SLC) having two possible memory states and therefore capable of storing one bit of data. For example, a first memory state “0” may correspond to a first voltage range, and a second memory state “1” may correspond to a second voltage range. In some implementations, each memory cell 306 may be a multi-level cell (MLC) storing more than a single bit of data in more than four memory states. For example, a MLC can store two bits per cell (also known as Double-Level Cell), three bits per cell (also known as Triple-Level Cell (TLC)), four bits per cell (also known as Quad-Level Cell (QLC)), five bits per cell (also known as Penta-level cell (PLC)), or more than five bits per cell. Each MLC may be programmed to take a range of possible nominal storage values. In one example, if each MLC stores two bits of data, the MLC may be programmed to take one of three possible programming levels from the erase state by writing one of three possible nominal storage values into the cell, and the fourth nominal storage value may be used for the erase state.

As shown in FIG. 3B, each memory string 308 may include a bottom select transistor 310 at its source end (also known as source-side select transistor, which includes a source select gate, BSG) and a top select transistor 312 at its drain end (also known as drain select transistor, which includes a drain select gate, TSG). The source select transistor BSG 310 and the drain select transistor TSG 312 may be configured to activate the selected memory string 308 during read and program operations. In some implementations, the sources of memory strings 308 in the same block 304 are coupled by the same source line (SL) 314 (e.g., a common SL). In other words, according to some implementations, all memory strings 308 in the same block 304 may have an array common source (ACS). According to some implementations, the TSG 312 of each memory string 308 is coupled to a respective bit line (BL) 316, from which data can be read or written via an output bus (not shown). In some implementations, each memory string 308 is configured to be selected or deselected by applying a select voltage (e.g., higher than a threshold voltage of the transistor having TSG 312) or a deselect voltage (e.g., 0V) to the corresponding TSG 312 via one or more TSG lines 313, and/or by applying a select voltage (e.g., higher than a threshold voltage of the transistor having BSG 310) or a deselect voltage (e.g., 0V) to the corresponding BSG 310 via one or more BSG lines 315.

As shown in FIG. 3B, the memory strings 308 may be organized into a plurality of blocks 304, each of which has a common source line 314 (e.g., coupled to ground). In some implementations, each block 304 is a basic data unit for an erase operation, i.e., all memory cells 306 on the same block 304 are erased at the same time. In order to erase the memory cells 306 in the selected block 304, the source line 314 of the selected block 304 and unselected blocks 304 on the same plane as the selected block 304 may be biased coupled with an erase voltage (Vers) (e.g., high positive voltage (e.g., 20V or higher)). In some examples, the erase operation may be performed at a half block level, at a quarter block level, or at a level of any suitable fraction of a block or any suitable number of blocks. The memory cells 306 of adjacent memory strings 308 may be coupled by word lines 318, and the word lines 318 select which row of memory cells 306 is to be affected by read and program operations. In some implementations, with reference to the above FIG. 3A, a plurality of memory cells are separated by an top select gate isolation structure and a gate isolation structure. A plurality of memory cells between the top select gate isolation structure and the gate isolation structure are arranged in a plurality of memory cell rows, each being parallel to the gate isolation structure and the top select gate isolation structure. The memory cells in slices that share the same word line form a physical page. Each physical page 320 may be mapped to at least one logical page, according to the storage mode (e.g., SLC or MLC as described above) of the corresponding memory cells 306. The logical page may constitute the basic data unit for program operations and read operations.

Referring to FIG. 3A and FIG. 3B, each memory cell 306 of the plurality of memory cells is coupled to a corresponding word line 318, and each memory string 308 is coupled to a corresponding bit line 316 by a corresponding select transistor, such as a top select transistor (TSG) 312.

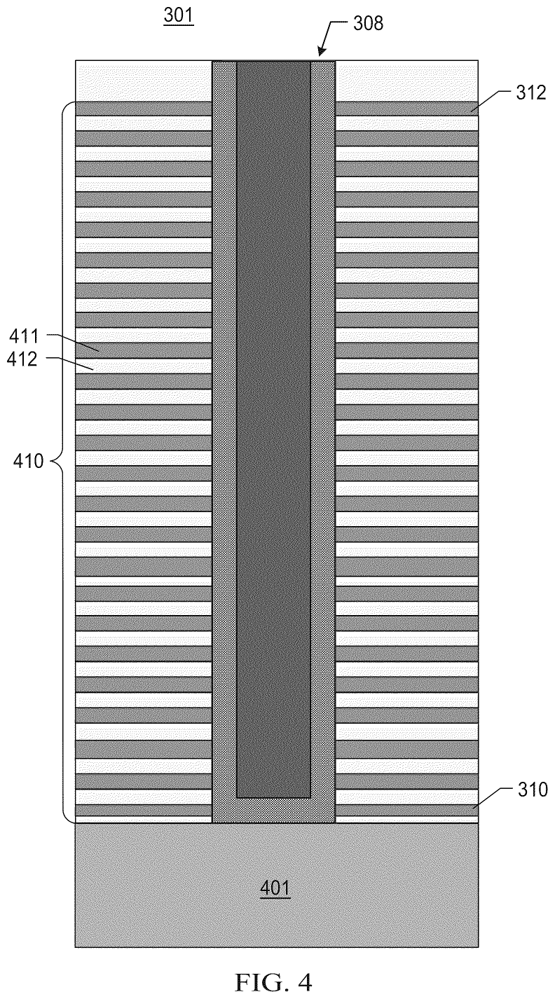

FIG. 4 shows a schematic cross-sectional view of an exemplary memory cell array 301 including a memory string 308 (for example, NAND) according to some aspects of the present disclosure. As shown in FIG. 4, the NAND memory cell array 301 may comprise a stacked structure 410, which includes a plurality of gate layers 411 and a plurality of insulating layers 412 alternately stacked in turn and a channel structure vertically penetrating the gate layers 411 and the insulating layers 412. The channel structure is coupled to each gate layer to form a memory cell, and the channel structure is coupled to a plurality of gate layers in the stacked structure 410 to form a memory string 308. The gate layers 411 and the insulating layers 412 may be alternately stacked, and two adjacent gate layers 411 are separated by an insulating layer 412.

The constituent material of the gate layers 411 may include a conductive material. The conductive material includes, but not limited to, tungsten (W), cobalt (Co), copper (Cu), aluminum (Al), polysilicon, doped silicon, silicide, or any combination thereof. In some implementations, each gate layer 411 may include a metal layer, for example, a tungsten layer. In some implementations, each gate layer 411 may include a doped polysilicon layer. Each gate layer 411 may include a control gate surrounding a memory cell. The gate layer 411 at the top of the stack structure 410 may extend laterally as a top select gate line, and the gate layer 411 at the bottom of the stack structure 410 may extend laterally as a bottom select gate line, and the gate layers 411 extending laterally between the top select gate line and the bottom select gate line may serve as word line layers.

In some implementations, the stack structure 410 may be disposed on a substrate 401. The substrate 401 may include silicon (e.g., monocrystalline silicon), silicon germanium (SiGe), gallium arsenide (GaAs), germanium (Ge), silicon on insulator (SOI), germanium on insulator (GOI) or any other suitable material.

In some implementations, the memory string 308 includes a channel structure that extends vertically through the stack structure 410. In some implementations, the channel structure includes a channel hole filled with semiconductor material(s) (e.g., as a semiconductor channel) and dielectric material(s) (e.g., as a memory film). In some implementations, the semiconductor channel comprises silicon, such as polysilicon. In some implementations, the memory film is a composite dielectric layer including a tunneling layer, a memory layer (also referred to as a “charge trapping/storage layer”) and a blocking layer. The channel structure may have a cylindrical shape (e.g., a pillar shape). According to some implementations, the semiconductor channel, the tunneling layer, the memory layer and the blocking layer are arranged radially from the center of the cylinder toward the outer surface of the cylinder in this order. The tunneling layer may include silicon oxide, silicon oxynitride or any combination thereof. The memory layer may include silicon nitride, silicon oxynitride or any combination thereof. The blocking layer may comprise silicon oxide, silicon oxynitride, high dielectric constant (high k) dielectric or any combination thereof. In one example, the memory film may include a composite layer of silicon oxide/silicon oxynitride/silicon oxide (ONO).

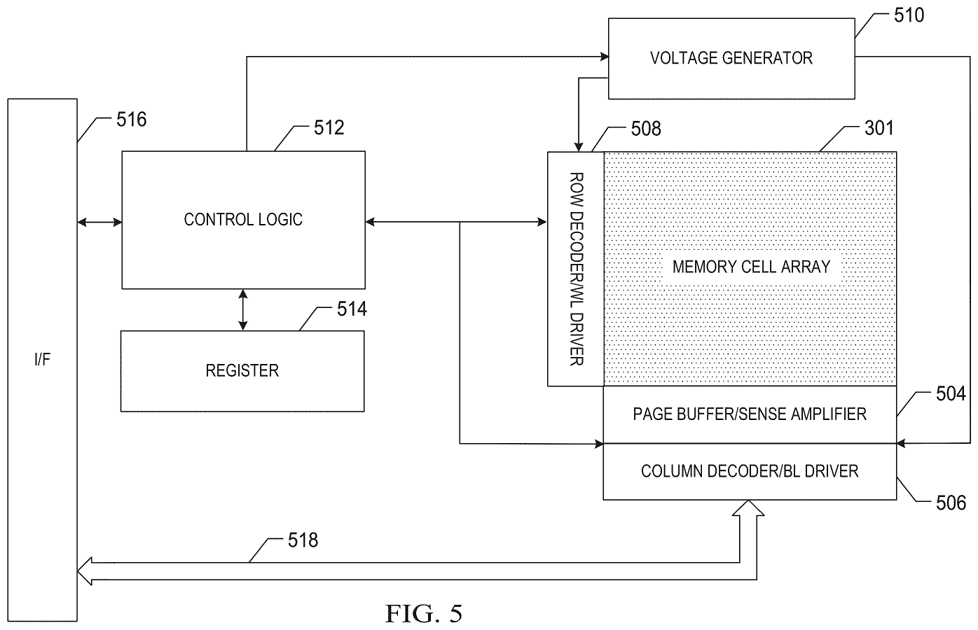

Referring back to FIG. 3B, the peripheral circuit 302 may be coupled to the memory cell array 301 through the bit lines 316, the word lines 318, the source lines 314, the BSG lines 315, and the TSG lines 313. The peripheral circuit 302 may include any suitable analog, digital, and mixed-signal circuit for facilitating operations of the memory cell array 301 by applying voltage and/or current signals to and sensing voltage and/or current signals from each of the target memory cells 306 via the bit lines 316, the word lines 318, the source lines 314, the BSG lines 315, and the TSG lines 313. The peripheral circuit 302 may include various types of peripheral circuits formed using metal-oxide-semiconductor (MOS) technology. For example, FIG. 5 shows some exemplary peripheral circuits. The peripheral circuit 302 may include a page buffer/sense amplifier 504, a column decoder/bit line driver 506, a row decoder/word line driver 508, a voltage generator 510, control logic 512, a register 514, an interface 516, and a data bus 518. In some examples, additional peripheral circuits not shown in FIG. 5 may also be included.

The page buffer/sense amplifier 504 may be configured to read data from and program (write) data to the memory cell array 301 based on control signals from the control logic 512. In one example, the page buffer/sense amplifier 504 may store the programmed data (written data) that is to be programmed into the memory cell array 301. In another example, the page buffer/sense amplifier 504 may perform a program verify operation to ensure that data has been properly programmed into the memory cells 306 coupled to the selected word lines 318. In yet another example, the page buffer/sense amplifier 504 may sense low power signals from the bit lines 316 representing data bits stored in memory cells 306 and amplify small voltage swings to recognizable logic levels in read operations. The column decoder/bit line driver 506 may be configured to be controlled by the control logic 512 and to select one or more memory strings 308 by applying bit line voltages generated from the voltage generator 510.

The row decoder/word line driver 508 may be configured to be controlled by the control logic 512 and to select/deselect a block 304 of the memory cell array 301 and to select/deselect word lines 318 of the block 304. The row decoder/word line driver 508 may also be configured to drive the word lines 318 using the word line voltages generated from the voltage generator 510. In some implementations, the row decoder/word line driver 508 may also select/deselect and drive the BSG lines 315 and TSG lines 313. As described in detail below, the row decoder/word line driver 508 is configured to perform a program operation on the memory cells 306 coupled to the selected word line(s) 318. The voltage generator 510 may be configured to be controlled by the control logic 512 and to generate a word line voltage (e.g., a read voltage, a program voltage, a pass voltage, a channel boost voltage, a verify voltage, etc.), a bit line voltage, and a source line voltage to be supplied to the memory cell array 301.

The control logic 512 may be coupled to each of other parts of the peripheral circuit described above and be configured to control the operations of each of other parts of the peripheral circuit. The register 514 may be coupled to the control logic 512 and include a status register, a command register and an address register, for storing status information, command operation code (OP code), and command address for controlling each operations of the peripheral circuit. The interface 516 may be coupled to the control logic 512 and act as a control buffer to buffer control commands received from a host system (not shown) and relay them to the control logic 512, and to buffer status information received from the control logic 512 and relay them to the host system. The interface 516 may also be coupled to the column decoder/bit line driver 506 via the data bus 518 and act as a data I/O interface and a data buffer to buffer and relay data to or from the memory cell array 301.

In view of faster reading and writing and more durability of blocks in a memory device under the SLC mode, some blocks in a memory device having multi-bit memory cells such as MLC, TLC, QLC or PLC are configured in the SLC mode to access as a cache (which may be referred to as SLC cache) for caching data. When the memory device begins to write data, the data may be first written to the SLC cache, and then when the space configured as the SLC cache is full or about to be full, the data in the SLC cache may be moved to the MLCs, TLCs, QLCs or PLCs to release the SLC cache space.

Here, the corresponding storage mode in which the read and write operations are performed with the respective storage bits in a memory cell having multiple storage bits (such as MLC, TLC, QLC or PLC, etc.) of a block is called a normal storage mode; while the corresponding storage mode in which the read and write operations are performed with one storage bit in the memory cell having multiple storage bits (such as MLC, TLC, QLC or PLC, etc.) is called a high-speed storage mode or a SLC mode. It could be understood that when the memory cell adopts the high-speed storage mode, the reading and writing speed is faster, but there is a loss of utilization of memory space; while when the memory cell adopts the normal storage mode, the utilization of memory space is higher, but the reading and writing speed is relatively slow. Therefore, how to allocate the proportion of the above two factors in the memory device so as to optimize the performance of the memory device has practical significance. Generally, the storage mode is determined in units of blocks, that is, all memory cells in one block are to be determined to adopt a certain kind of storage mode, such as the normal storage mode or the high-speed storage mode, etc.

Dynamic SLC Cache is an algorithm for storage mode allocation which, as a key algorithm, is an important means for performance acceleration of memory devices and has been applied to more and more memory devices. Therefore, a simple and universal Dynamic SLC Cache algorithm is of great practical significance.

In some implementations, the Dynamic SLC Cache algorithm linearly controls the number of blocks used as the SLC cache, with the number of free blocks as an input parameter of the Dynamic SLC Cache algorithm and with a start threshold and a stop threshold as thresholds for enabling and disabling the SLC cache. Here, when user data is written into the memory device, usually, a block is firstly filled up and then a new block is opened. A free block is a blank block without any data written therein. A block with data written therein is as opposed thereto, and the data stored in such a block with data written therein includes valid data and invalid data. Here, the valid data includes data that has not been erased by the host system, instructed by the host system to be erased, updated by the host system, or rewritten by the host system, or the like. Conversely, the invalid data as opposed to the valid data includes data that has been erased by the host system, indicated by the host system to be erased, updated by the host system, or rewritten by the host system.

However, in the case where the number of blocks with data written therein is large but proportion of valid data in most or even all of the blocks with data written therein is low, the memory space that may be used actually by the memory system is still large although the number of free blocks is small. That is, the number of free blocks in this application scenario may not reflect the actual memory space of the memory device accurately. At this time, using the number of free blocks as the input parameter of Dynamic SLC Cache algorithm may make the algorithm misjudge, that is, it is judged that the available memory space of the memory system is insufficient and it is not suitable to further allocate blocks to adopt the high-speed storage mode. The problem that the performance degradation will occur soon after writing to the memory system originates from the algorithm distortion of the Dynamic SLC Cache algorithm because of misjudgment. In addition, it is too rigid and inflexible to simply use two fixed thresholds, the start threshold and the stop threshold, as the trigger conditions for enabling and disabling SLC cache.

In view of one or more of the above problems, a memory system, an operating method thereof, and a storage medium are provided by the implementations of the present disclosure. The memory system 102 comprises: a memory device 104 including a plurality of blocks, wherein a block includes a plurality of memory cells; a memory controller 106 coupled to the memory device 104 and configured to: determine a storage mode for a block based on a total amount of valid data in all of the plurality of blocks; wherein data reading and writing with different rates are to be performed for different storage modes by configuring the number of data bits stored in each memory cell in the block.

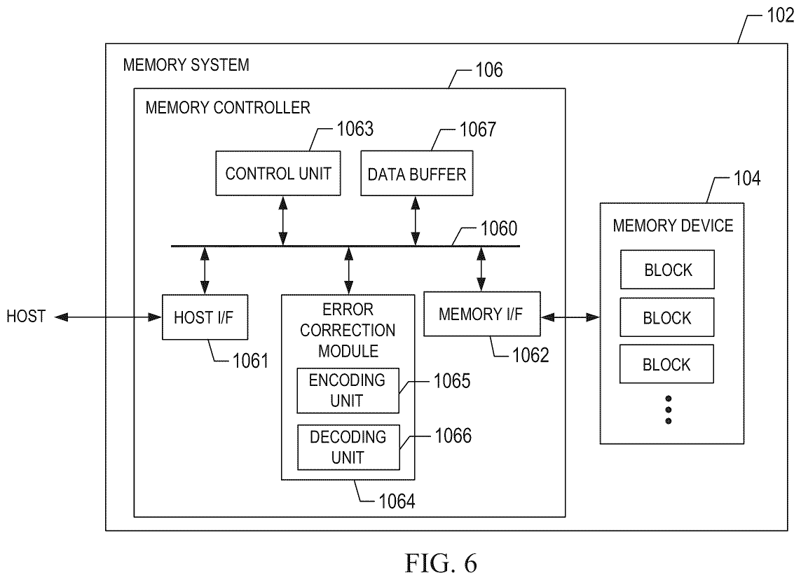

In some exemplary implementations, as shown in FIG. 6, the memory system 102 is coupled to a host system (HOST) to perform various feedbacks in response to instructions from the host system. The memory system 102 may include a memory controller 106 and a memory device 104, wherein the memory controller 106 is to control the memory device 104 to perform operations such as read, write, erase, and the like. The memory controller 106 and the memory device 104 may be coupled in any way. The memory controller 106 may include a host interface (I/F) 1061, a memory interface (I/F) 1062, a control unit 1063, an error correction module 1064, a data buffer 1067 and a second bus 1060. The host interface 1061 is a connection interface between the host system 108 and the memory controller 106, and it allows the host system and the memory controller to communicate according to a particular protocol, transmitting read and write requests and performing other operations. The memory interface 1062 is a connection interface between the memory controller 106 and the memory device 104, and it is configured to implement data transmission between the memory controller 106 and the memory device 104. The control unit 1063 is configured to control the memory system 106 as a whole. In some exemplary implementations, the control unit 1063 may be for example a central processing unit (CPU), a microprocessor (MCU) or the like. The error correction module 1064 may further include an encoding unit 1065 and a decoding unit 1066. The encoding unit 1065 is configured to encode the data to be stored so as to get check data; and the decoding unit 1066 is configured to decode the check data to detect and correct possible error data in the data transmission. The buffer 1067 is configured to buffer data.

In some implementations, the valid data refers to data that has practical significance for use. In some examples, it may include data that has not been erased by the host system, indicated by the host system to be erased, updated by the host system, or rewritten by the host system, etc. The storage mode is in relation to the number of storage bits to be used actually by a memory cell in a block, and different storage modes correspond to different numbers of storage bits to be used actually by a memory cell, which in turn correspond to different speeds of reading and writing. For example, the speed of reading and writing is fast when using one of a plurality of storage bits corresponding to a memory cell having the plurality of storage bits (e.g., MLC, TLC, QLC or PLC, or the like); while the speed of reading and writing is slow when using a plurality of storage bits corresponding to a memory cell having the plurality of memory bits (e.g., MLC, TLC, QLC or PLC, or the like).

As previously mentioned, the invalid data is as opposed to the valid data, and it refers to the data that has no practical significance for use. In some examples, the invalid data may include data that has been erased by the host system, indicated by the host system to be erased, updated by the host system, or rewritten by the host system, etc. It could be understood that, as for invalid data, the memory space occupied by invalid data may be reclaimed by the memory system in idle state through garbage collection, internal data copyback and so on. That is, the part of the memory space occupied by the invalid data contained in the block with data written therein may be reused. In view of this, the total amount of valid data in all of a plurality of blocks in the memory system may reflect more objectively the actual storage situation of the memory system, compared with the number of all free blocks among the plurality of blocks of the memory system.

In implementations of the present disclosure, the influence of invalid data on the actual valid memory space may be eliminated, by using the total amount of valid data in all of a plurality of blocks of a memory system to determine the storage mode for a block. It is more accurate and thus covers broader application scenes, compared to using the number of free blocks of a memory device to determine the storage mode for a block.

In some implementations, the memory controller 106 is configured to: acquire the total amount of valid data in all of the plurality of blocks; calculate a ratio of the total amount of valid data to a total memory space of the plurality of blocks to obtain a proportion of valid data; and determine, based on the proportion of valid data, the storage mode for a new block to be opened.

Considering the fact that the total amount of valid data in all of the plurality of blocks in the memory system 102 is an absolute value, it is not convenient for memory systems with different sizes of total memory space to compare uniformly, therefore the concept of proportion of valid data is proposed herein. Here, the proportion of valid data refers to a ratio of the sum of the valid data of all of the respective blocks for storing user data in a memory system 102 to the total memory space for storing user data in the memory system 102.

As mentioned above, when the user data is written into the memory device 104, usually, one block will be firstly filled up and then a new block will be opened for storing data. In the implementations of the present disclosure, the block for which the storage mode is to be determined refers to a new block to be opened. That is, for the new block to be opened, the storage mode may be firstly determined, and then it is used for storing data according to the determined storage mode.

In some implementations, a block comprises a plurality of pages; and the memory controller 106 is further configured to acquire a count of pages occupied by valid data in all of the plurality of blocks to obtain the total amount of valid data.

Here, the pages refer to logical pages. In some exemplary implementations, the count of corresponding pages occupied by valid data in each of the blocks may be acquired, by retrieving a record in firmware (FW) regarding the count of corresponding pages occupied by valid data in each of the blocks. Then, the counts of corresponding pages occupied by valid data in all of the plurality of blocks are summed up to obtain the total amount of valid data.

In some implementations, the storage modes comprise a first mode and a second mode; wherein in the first mode, the data bits stored in each memory cell of the block comprise one bit; and in the second mode, the data bits stored in each memory cell of the block comprise multiple bits; the memory controller is configured to: configure dynamically the number of blocks adopting the first mode when the proportion of valid data is greater than or equal to a first threshold; stop configuring dynamically the number of blocks adopting the first mode when the proportion of valid data is greater than or equal to a second threshold; wherein the first threshold is less than the second threshold.

In the implementations of the present disclosure, the valid written data of the memory system may be effectively tracked by using the total amount of current valid data of the memory system as an input parameter. The Dynamic SLC Cache algorithm is enabled when the total amount of valid data reaches a first threshold, and the Dynamic SLC Cache algorithm is disabled when the total amount of valid data reaches a second threshold.

Here, the first mode may correspond to the aforementioned high-speed storage mode and the second mode may correspond to the aforementioned normal storage mode. The reading and writing speed corresponding to the first mode is greater than that corresponding to the second mode. The first threshold may be considered as a critical value of proportion of valid data, for starting the dynamic configuration of the number of blocks adopting the first mode, and the second threshold may be considered as a critical value of proportion of valid data, for stopping the dynamic configuration of the number of blocks adopting the first mode. The first threshold and the second threshold may be adjusted based on actual empirical data. In some exemplary implementations, the range for the first threshold is 0%-5% and the range for the second threshold is 40%-70%. As an example, the first threshold is 0% and the second threshold is 50%.

The first threshold is less than the second threshold, and when comparing the proportion of valid data with the first threshold and the second threshold, if the proportion of valid data is less than the first threshold or greater than the second threshold, the storage mode for the new block to be opened may be directly determined as the second mode. If the proportion of valid data is between the first threshold and the second threshold, the configuration scheme for the number of blocks adopting the first mode may be further refined.

In some implementations, the memory controller 106 is configured to: configure the number of blocks adopting the first mode to be a first number when the proportion of valid data is a first proportion; configure the number of blocks adopting the first mode to be a second number when the proportion of valid data is a second proportion; configure the number of blocks adopting the first mode to be a third number when the proportion of valid data is a third proportion; wherein the first proportion is less than the second proportion, and the second proportion is less than the third proportion; the first number is greater than the second number, and the second number is greater than the third number.

Here, the values of the first proportion, the second proportion and the third proportion increase in turn and they are all between the first threshold and the second threshold. The configurations of the numbers of blocks adopting the first mode are different for different proportions of valid data, and with the increase of the proportion of valid data, the number of blocks adopting the first mode decreases.

A fitting line will be obtained by fitting the proportion of valid data between the first threshold and the second threshold with the number of blocks adopting the first mode. The first point corresponding to the first proportion and the first number, the second point corresponding to the second proportion and the second number, and the third point corresponding to the third proportion and the third number are all located on the fitting line. The fitting line may be a curve, a plurality of line segments, etc., and may be adjusted correspondingly according to the empirical data obtained from different actual scenes.

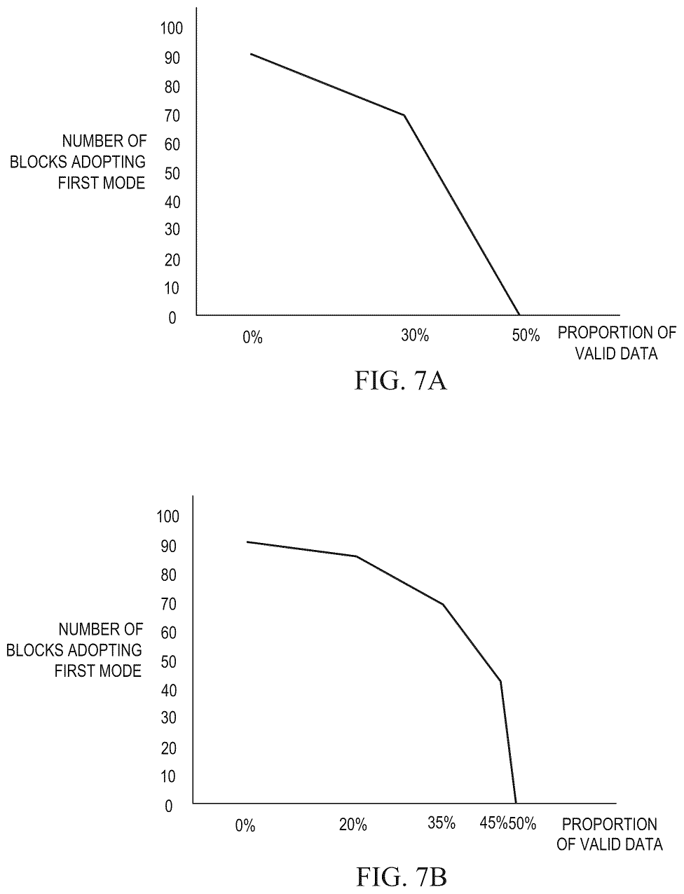

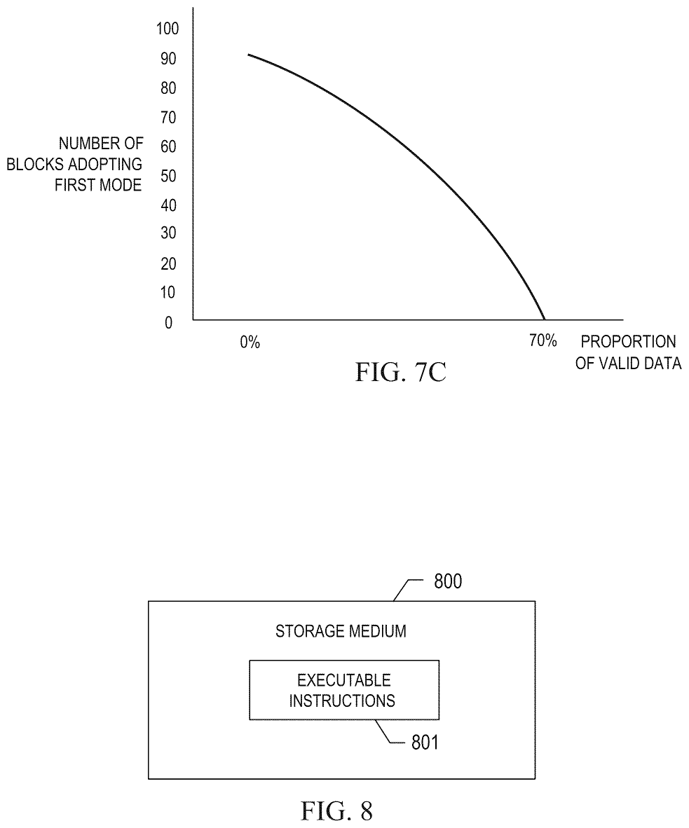

The actual situation of the memory system may be fitted with different fitting lines in consideration of the flexibility of the memory system in the implementations of the present disclosure. Several examples will be given below with reference to FIGS. 7A to 7C.

In some exemplary implementations, the proportion of valid data is linearly correlated with the number of blocks adopting the first mode, both between the first proportion and the second proportion and between the second proportion and the third proportion; a ratio of a difference between the second number and the first number to a difference between the second proportion and the first proportion is different from a ratio of a difference between the third number and the second number to a difference between the third proportion and the second proportion.

As shown in FIG. 7A, by way of example, in FIG. 7A the vertical coordinate indicates the number of blocks adopting the first mode, and the horizontal coordinate indicates the proportion of valid data (POVD), wherein the fitting line regarding the number of blocks adopting the first mode and the proportion of valid data POVD comprises two line segments. In this case, the first threshold is overlapped with the first proportion, the second threshold is overlapped with the third proportion, and the number of blocks adopting the first mode between the first point corresponding to the first proportion and the first number and the second point corresponding to the second proportion and the second number is linearly correlated with the POVD, and the number of blocks adopting the first mode between the second point corresponding to the second proportion and the second number and the third point corresponding to the third proportion and the third number is linearly correlated with the POVD. As an example, 90 blocks are to be used as the SLC cache when the POVD is 0; 70 blocks are to be used as the SLC cache when the POVD is 30%; and 0 block is to be used as the SLC cache when the POVD is 50%.

As shown in FIG. 7B, by way of example, in FIG. 7B the vertical coordinate indicates the number of blocks adopting the first mode, and the horizontal coordinate indicates the proportion of valid data POVD, wherein the fitting line regarding the number of blocks adopting the first mode and the proportion of valid data POVD comprises four line segments. In this case, the first proportion, the second proportion and the third proportion are all positioned between the first threshold and the second threshold. As an example, 90 blocks are to be used as the SLC cache when the POVD is 0; 85 blocks are to be used as the SLC cache when the POVD is 20%; 70 blocks are to be used as the SLC cache when the POVD is 35%; 42 blocks are to be used as the SLC cache when the POVD is 45%; and 0 block is to be used as the SLC cache when the POVD is 50%.

The first threshold, the first proportion, the second proportion, the third proportion and the second threshold shown in FIGS. 7A and 7B are examples only and are not used to limit the specific values of the first threshold, the first proportion, the second proportion, the third proportion and the second threshold in the implementations of the present disclosure. The specific values of the first threshold, the first proportion, the second proportion, the third proportion and the second threshold may be adjusted according to the actual situation, in the implementations of the present disclosure.

In some other implementations, the fitting line regarding the number of blocks adopting the first mode and the proportion of valid data (POVD) may also include more line segments.

In some exemplary implementations, for a fitting line with multiple line segments: a one-dimensional array threshold[N] is first defined, where N represents the number of line segments that is required plus 1, and then each threshold value is initialized as needed. Each time a new block is to be opened, the number of SLC cache blocks allowed by the memory system currently is determined through interpolation calculation according to the current POVD of the memory system. If it is found that the number of existing SLC blocks in the memory system is greater than the calculated number of SLC cache blocks, the system cannot open a SLC block as data block at this time, otherwise it will open a SLC block as data block.

As shown in FIG. 7C, by way of example, in FIG. 7C the vertical coordinate indicates the number of blocks adopting the first mode, and the horizontal coordinate indicates the proportion of valid data POVD, wherein the fitting line regarding the number of blocks adopting the first mode and the proportion of valid data POVD comprises a curve.

The fitting lines regarding the number of blocks adopting the first mode and the proportion of valid data (POVD) shown in FIGS. 7A, 7B and 7C are examples only and are not used to limit the mapping relationship between the number of blocks adopting the first mode and the proportion of valid data (POVD) in the implementations of the present disclosure.

Considering the fact that it may be time consuming to directly calculate the number of blocks adopting the first mode according to the current proportion of valid data (POVD) of the memory system when the fitting line regarding the number of blocks adopting the first mode and the POVD is a curve or contains a relatively large number of line segments, the number of blocks adopting the first mode may be obtained by way of querying a mapping table.

In some implementations, the memory controller 106 is configured to: query a target mapping table using the proportion of valid data to determine the number of blocks adopting the first modes; the target mapping table includes a correspondence relationship between values of different proportions of valid data and corresponding numbers of blocks adopting the first mode.

Here, it is necessary to obtain in advance a target mapping table including the correspondence relationship between the values of different proportions of valid data and the corresponding numbers of blocks adopting the first mode according to the actual experimental data, and to store the target mapping table in the memory device 104 or firmware.

In some implementations, the memory controller 106 is further configured to: select the target mapping table from among a plurality of mapping tables before querying the target mapping table; the correspondence relationship between the different proportions of valid data and the corresponding numbers of blocks adopting the first mode, contained in each of the plurality of mapping tables, is different from one another.

Considering the fact that the correspondence relationship between the values of different proportions of valid data and the corresponding numbers of blocks adopting the first mode may vary in different application scenarios, the mapping tables corresponding to the respective scenarios may be obtained according to different application scenarios, when obtaining the mapping tables including the correspondence relationship between the values of different proportions of valid data and the corresponding numbers of blocks adopting the first mode. After that, the target mapping table to be used may be determined at the time when the memory system is powered up or at other time before the target mapping table needs to be queried.

Storing the mapping tables corresponding to the respective scenarios in advance and then selecting the corresponding mapping table according to the actual needs may be suitable for more scenarios, and the dynamical adjustment is more flexible and effective.

In some implementations, the memory controller 106 is further configured to: in response to a new block needs to be opened for data writing: configure the new block to perform the data writing with the first mode when the number of blocks adopting the first mode determined based on the proportion of valid data is greater than the current number of blocks actually adopting the first mode; configure the new block to perform the data writing with the second mode when the number of blocks adopting the first mode determined based on the proportion of valid data is less than or equal to the current number of blocks actually adopting the first mode.

Here, before opening a new block, the number of blocks adopting the first mode is determined firstly according to the current proportion of valid data POVD of the memory system. Then, the current number of blocks actually adopting the first mode of the memory system may be counted, and the number of blocks actually adopting the first mode of the memory system may be compared with the number of blocks adopting the first mode determined by the proportion of valid data. The storage mode for the new block may be determined as the first mode, i.e., the new block is to be used as the SLC cache, when the current number of blocks actually adopting the first mode is less than the number of blocks adopting the first mode determined based on the proportion of valid data, which indicates that the number of blocks actually used by the memory system as the SLC cache has not reached the upper limit allowed by the memory system. The storage mode for the new block may be determined as the second mode, i.e., the new block is to be used in the normal storage mode, when the current number of blocks actually adopting the first mode is larger than or equal to the number of blocks adopting the first mode determined based on the proportion of valid data, which indicates that the number of blocks actually used by the memory system as the SLC cache has reached the upper limit allowed by the memory system.

In some implementations, the memory system includes a universal flash storage (UFS) or a solid state disk (SSD). The memory device includes NAND-type memory.

In the implementations of the present disclosure, the memory controller in the memory system determines a storage mode for a block based on a total amount of valid data in all of the plurality of blocks of the memory device; wherein data reading and writing with different rates are to be preformed for different storage modes by configuring the number of data bits stored in each memory cell in the block. In the implementations of the present disclosure, the storage mode for a block is determined based on the total amount of valid data in all of the plurality of blocks in the memory device, thus the misjudgment that may occur when the distribution of valid data in most or all of blocks is low can be avoided, thereby being applicable to a wide range of application scenarios.

Further, an implementation of the present disclosure provides an operating method of a memory system, comprising: determining a storage mode for a block based on a total amount of valid data in all of a plurality of blocks in a memory device of the memory system; wherein data reading and writing with different rates are to be performed for different storage modes by configuring the number of data bits stored in each memory cell in the block.

In some implementations, the method further comprises: acquiring the total amount of valid data in all of the plurality of blocks; calculating a ratio of the total amount of valid data to a total memory space of the plurality of blocks to obtain the proportion of valid data; determining, based on the proportion of valid data, the storage mode for a new block to be opened.

In some implementations, the storage modes comprise a first mode and a second mode; wherein in the first mode, the data bits stored in each memory cell of the block comprise one bit; and in the second mode, the data bits stored in each memory cell of the block comprise multiple bits; determining, based on the proportion of valid data, the storage mode for the block comprises: configuring dynamically the number of blocks adopting the first mode when the proportion of valid data is greater than or equal to a first threshold; stopping configuring dynamically the number of blocks adopting the first mode when the proportion of valid data is greater than or equal to a second threshold; wherein the first threshold is less than the second threshold.

In some implementations, the method further comprises: configuring the number of blocks adopting the first mode to be a first number when the proportion of valid data is a first proportion; configuring the number of blocks adopting the first mode to be a second number when the proportion of valid data is a second proportion; configuring the number of blocks adopting the first mode to be a third number when the proportion of valid data is a third proportion; wherein the first proportion is less than the second proportion, and the second proportion is less than the third proportion; the first number is greater than the second number, and the second number is greater than the third number.

In some implementations, the proportion of valid data is linearly correlated with the number of blocks adopting the first mode, both between the first proportion and the second proportion and between the second proportion and the third proportion; a ratio of a difference between the second number and the first number to a difference between the second proportion and the first proportion is different from a ratio of a difference between the third number and the second number to a difference between the third proportion and the second proportion.

In some implementations, the method further comprises: querying a target mapping table using the proportion of valid data to determine the number of blocks adopting the first mode; the target mapping table includes a correspondence relationship between values of different proportions of valid data and corresponding numbers of blocks adopting the first mode.

In some implementations, the method further comprises: selecting the target mapping table from among a plurality of mapping tables before querying the target mapping table; the correspondence relationship between the different proportions of valid data and the corresponding numbers of blocks adopting the first mode, contained in each of the plurality of mapping tables, is different from one another.

In some implementations, the method further comprises: in response to a new block needs to be opened for data writing: configuring the new block to perform the data writing with the first mode when the number of blocks adopting the first mode determined based on the proportion of valid data is greater than the current number of blocks actually adopting the first mode; configuring the new block to perform the data writing with the second mode when the number of blocks adopting the first mode determined based on the proportion of valid data is less than or equal to the current number of blocks actually adopting the first mode.

In some implementations, a block comprises a plurality of pages; acquiring the total amount of valid data in all of the plurality of blocks comprises: acquiring a count of pages occupied by valid data in all of the plurality of blocks to obtain the total amount of valid data.

In some implementations, the valid data includes data that has not been erased, indicated to be erased, updated or rewritten by a host system.

The operating method of the memory system in the above implementations may be understood with reference to the exemplary schemes of storage mode determination described in the memory system in the aforementioned implementations.

Still further, an implementation of the present disclosure provides a storage medium having stored thereon executable instructions which, when being executed, may implement operations of the method of the implementations of the present disclosure.

In some exemplary implementations, the storage medium may be ferromagnetic random access memory (FRAM), read-only memory (ROM), programmable read-only memory (PROM), erasable programmable read-only memory (EPROM), electrically erasable programmable read-only memory (EEPROM), flash memory, magnetic surface memory, optical disc, or compact disc read-only memory (CD-ROM) or the like, or various devices including one or any combination of the above memory devices.

In some implementations, the executable instructions may be written in any form of programming language (including compiled or interpreted language, or declarative or procedural language) in the form of program, software, software module, scripts or code, and may be deployed in any form including being deployed as a stand-alone program or as modules, components, subroutines or other units suitable for use in computation environment.

As an example, the executable instructions may, but not necessarily, correspond to files in the file system, and may be stored in a portion of a file holding other programs or data, such as in one or more scripts in a HTML (hyper text markup language) document, in a single file dedicated to the program in question, or in multiple collaborative files (such as files storing one or more modules, subroutines or code portions).

As an example, the executable instructions may be deployed to be executed on one electronic device or on multiple electronic devices located at one location, or on multiple electronic devices distributed at multiple locations and interconnected through a communication network.

FIG. 8 is a schematic block diagram of a readable storage medium provided by an implementation of the present disclosure. The implementation of the present disclosure provides a readable storage medium 800, which stores executable instructions 801. The executable instructions 801, when executed by a processor, may implement the operating method of the memory system in the above-discussed technical solutions. The operating method includes: determining a storage mode for a block based on a total amount of valid data in all of the plurality of blocks; wherein data reading and writing with different rates are to be performed for different storage modes by configuring the number of data bits stored in each memory cell in the block.

The methods disclosed in the method implementations of the present disclosure may be arbitrarily combined without conflict to obtain new method implementations. References to “one implementation” or “an implementation” throughout the specification mean that particular features, structures or characteristics related to the implementation are to be included in at least one implementation of the present disclosure. Thus, the phrases “in one implementation” or “in an implementation” appearing throughout the specification do not necessarily refer to the same implementation. In addition, these particular features, structures or characteristics may be combined in any appropriate way in one or more implementations. In various implementations of the present disclosure, the sequence numbers in the above-mentioned various processes do not indicate the sequence of execution, and the sequence of execution for the various processes should be determined by their functions and inherent logic, and should not constitute any limitation on the practice of the implementations of the present disclosure. The above serial numbers of implementations of the present disclosure are for illustration only and do not represent the relative merits of the implementations.

The methods disclosed in the method implementations of the present disclosure may be arbitrarily combined without conflict to obtain new method implementations.

The foregoing are only exemplary implementations of the present disclosure, and the scope of protection of the present disclosure is not limited thereto. Any variation or alternative that can be readily contemplated by those skilled in the art within the scope of the present disclosure shall fall within the scope of protection of the present disclosure. Therefore, the scope of protection of the present disclosure shall be subject to the scope of protection of the claims.

What is claimed is:

1. A memory system, comprising:
a memory device including a plurality of blocks, wherein a block includes a plurality of memory cells; and
a memory controller coupled to the memory device and configured to:
determine a storage mode for based on a total amount of valid data in all of the plurality of blocks, different storage modes based on a number of data bits stored in each memory cell in the block.

2. The memory system of claim 1, wherein the memory controller is configured to:
acquire the total amount of valid data in all of the plurality of blocks;
calculate a ratio of the total amount of valid data to a total memory space of the plurality of blocks to obtain a proportion of valid data; and
determine, based on the proportion of valid data, the storage mode for a new block to be opened.

3. The memory system of claim 2, wherein the different storage modes comprise a first mode and a second mode; wherein in the first mode, the data bits stored in each memory cell of the block comprise one bit; and in the second mode, the data bits stored in each memory cell of the block comprise multiple bits;
the memory controller is configured to:
configure dynamically a number of blocks adopting the first mode when the proportion of valid data is greater than or equal to a first threshold; and
stop configuring dynamically the number of blocks adopting the first mode when the proportion of valid data is greater than or equal to a second threshold; wherein the first threshold is less than the second threshold.

4. The memory system of claim 3, wherein the memory controller is configured to:
configure the number of blocks adopting the first mode to be a first number when the proportion of valid data is a first proportion;
configure the number of blocks adopting the first mode to be a second number when the proportion of valid data is a second proportion; and
configure the number of blocks adopting the first mode to be a third number when the proportion of valid data is a third proportion;
wherein the first proportion is less than the second proportion, and the second proportion is less than the third proportion; the first number is greater than the second number, and the second number is greater than the third number.

5. The memory system of claim 4, wherein the proportion of valid data is linearly correlated with the number of blocks adopting the first mode, both between the first proportion and the second proportion and between the second proportion and the third proportion; and
a ratio of a difference between the second number and the first number to a difference between the second proportion and the first proportion is different from a ratio of a difference between the third number and the second number to a difference between the third proportion and the second proportion.

6. The memory system of claim 3, wherein the memory controller is configured to:
query a target mapping table using the proportion of valid data to determine the number of blocks adopting the first mode; the target mapping table includes a correspondence relationship between values of different proportions of valid data and corresponding numbers of blocks adopting the first mode.

7. The memory system of claim 6, wherein the memory controller is further configured to:
select the target mapping table from among a plurality of mapping tables before querying the target mapping table; the correspondence relationship between the values of different proportions of valid data and the corresponding numbers of blocks adopting the first mode, contained in each of the plurality of mapping tables, is different from one another.

8. The memory system of claim 3, wherein the memory controller is further configured to:
configure a new block to perform the data writing with the first mode when the number of blocks adopting the first mode determined based on the proportion of valid data is greater than a current number of blocks actually adopting the first mode; and
configure the new block to perform the data writing with the second mode when the number of blocks adopting the first mode determined based on the proportion of valid data is less than or equal to a current number of blocks actually adopting the first mode.

9. The memory system of claim 2, wherein a block comprises a plurality of pages;
the memory controller is further configured to:
acquire a count of pages occupied by valid data in all of the plurality of blocks to obtain the total amount of valid data.

10. The memory system of claim 1, wherein the valid data includes data that has not been erased, indicated to be erased, updated or rewritten by a host system.

11. An operating method of a memory system, comprising:
determining a storage mode for a block based on a total amount of valid data in all of a plurality of blocks in a memory device of the memory system; wherein different storage modes based on a number of data bits stored in each memory cell in the block.

12. The operating method of claim 11, further comprising:
acquiring the total amount of valid data in all of the plurality of blocks;
calculating a ratio of the total amount of valid data to a total memory space of the plurality of blocks to obtain a proportion of valid data; and
determining, based on the proportion of valid data, the storage mode for a new block to be opened.

13. The operating method of claim 12, wherein the different storage modes comprise a first mode and a second mode; wherein in the first mode, the data bits stored in each memory cell of the block comprise one bit; and in the second mode, the data bits stored in each memory cell of the block comprise multiple bits;
determining, based on the proportion of valid data, the storage mode for the block comprises:
configuring dynamically a number of blocks adopting the first mode when the proportion of valid data is greater than or equal to a first threshold; and
stopping configuring dynamically the number of blocks adopting the first mode when the proportion of valid data is greater than or equal to a second threshold; wherein the first threshold is less than the second threshold.

14. The operating method of claim 13, further comprising:
configuring the number of blocks adopting the first mode to be a first number when the proportion of valid data is a first proportion;
configuring the number of blocks adopting the first mode to be a second number when the proportion of valid data is a second proportion; and
configuring the number of blocks adopting the first mode to be a third number when the proportion of valid data is a third proportion;
wherein the first proportion is less than the second proportion, and the second proportion is less than the third proportion; the first number is greater than the second number, and the second number is greater than the third number.

15. The operating method of claim 14, wherein the proportion of valid data is linearly correlated with the number of blocks adopting the first mode, both between the first proportion and the second proportion and between the second proportion and the third proportion; and
a ratio of a difference between the second number and the first number to a difference between the second proportion and the first proportion is different from a ratio of a difference between the third number and the second number to a difference between the third proportion and the second proportion.

16. The operating method of claim 13, further comprising:
querying a target mapping table using the proportion of valid data to determine the number of blocks adopting the first mode; the target mapping table includes a correspondence relationship between values of different proportions of valid data and corresponding numbers of blocks adopting the first mode.

17. The operating method of claim 16, further comprising:
selecting the target mapping table from among a plurality of mapping tables before querying the target mapping table; the correspondence relationship between the values of different proportions of valid data and the corresponding numbers of blocks adopting the first mode, contained in each of the plurality of mapping tables, is different from one another.

18. The operating method of claim 13, further comprising:
configuring a new block to perform the data writing with the first mode when the number of blocks adopting the first mode determined based on the proportion of valid data is greater than a current number of blocks actually adopting the first mode; and
configuring the new block to perform the data writing with the second mode when the number of blocks adopting the first mode determined based on the proportion of valid data is less than or equal to a current number of blocks actually adopting the first mode.

19. The operating method of claim 12, wherein a block comprises a plurality of pages; acquiring the total amount of valid data in all of the plurality of blocks comprises:
acquiring a count of pages occupied by valid data in all of the plurality of blocks to obtain the total amount of valid data.

20. A storage medium having stored thereon executable instructions which, when being executed, implement an operating method of a memory system, comprising:
determining a storage mode for a block based on a total amount of valid data in all of a plurality of blocks in a memory device of the memory system; wherein different storage modes based on a number of data bits stored in each memory cell in the block.
